(19) United States
(12) Patent Application Publication
(10) Pub. No.: US 2026/0363101 A1
(43) Pub. Date: Nov. 12, 2026

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Yu-Shun Lin, Taipei City (TW); Cheng Yen Tsou, Taipei City (TW); I-Hsin Tsai, New Taipei City (TW); Sung-Hui Huang, Yilan County (TW); Hsien-Pin Hu, Hsinchu County (TW); Shang-Yun Hou, Hsinchu (TW); Yu-Yun Huang, Hsinchu County (TW)

(73) Assignee: Taiwan Semiconductor Manufacturing Company, Ltd., Hsinchu (TW)

(21) Appl. No.: 19/749,575

(22) Filed: Jul. 21, 2026

Related U.S. Application Data
(63) Continuation of application No. 18/412,567, filed on Jan. 14, 2024.

(51) Int. Cl. H10W 70/60; H10W 70/05; H10W 70/63; H10W 70/685; H10W 90/00; H10W 74/15

(52) U.S. Cl. CPC H10W 70/611; H10W 70/05; H10W 70/635; H10W 70/685; H10W 90/00; H10W 74/15; H10W 90/701; H10W 90/724; H10W 90/734

(57) ABSTRACT

A semiconductor device includes an interconnect structure. The interconnect structure includes a first conductive line in a first dielectric layer, a conductive via in a second dielectric layer, a second conductive line in a third dielectric layer and an etch stop layer. The second dielectric layer is disposed between the first and third dielectric layers, and a dielectric constant of the second dielectric layer is smaller than a dielectric constant of the first dielectric layer and a dielectric constant of the third dielectric layer. The etch stop layer is disposed directly below at least one of the first to third dielectric layers.

### CROSS-REFERENCE TO RELATED APPLICATION

This application is a continuation application of and claims the priority benefit of a prior application serial No. 18/412,567, filed on January 14, 2024. The entirety of the above-mentioned patent application is hereby incorporated by reference herein and made a part of this specification.

### BACKGROUND

The semiconductor industry has experienced rapid growth due to continuous improvements in the integration density of various electronic components (e.g., transistors, diodes, resistors, capacitors, etc.). For the most part, this improvement in integration density has come from repeated reductions in minimum feature size, which allows more of the smaller components to be integrated into a given area. These smaller electronic components may require smaller packages that utilize less area than previous packages. Currently, integrated fan-out packages are becoming increasingly popular for their compactness. How to ensure the reliability of the integrated fan-out packages has become a challenge in the field.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1G are schematic cross-sectional views of various stages in a method of forming a semiconductor device according to some embodiments.

FIG. 2 is a schematic cross-sectional view of a semiconductor device according to some embodiments.

FIG. 3A to FIG. 3J are schematic cross-sectional views of various stages in a method of forming a semiconductor device according to some embodiments.

FIG. 4 is a schematic cross-sectional view of a semiconductor device according to some embodiments.

FIG. 5A to FIG. 5G are schematic cross-sectional views of various stages in a method of forming a semiconductor device according to some embodiments.

FIG. 6A and FIG. 6B respectively illustrate a top view of a semiconductor device in accordance with some embodiments of the disclosure.

FIG. 7 illustrates a flowchart of a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

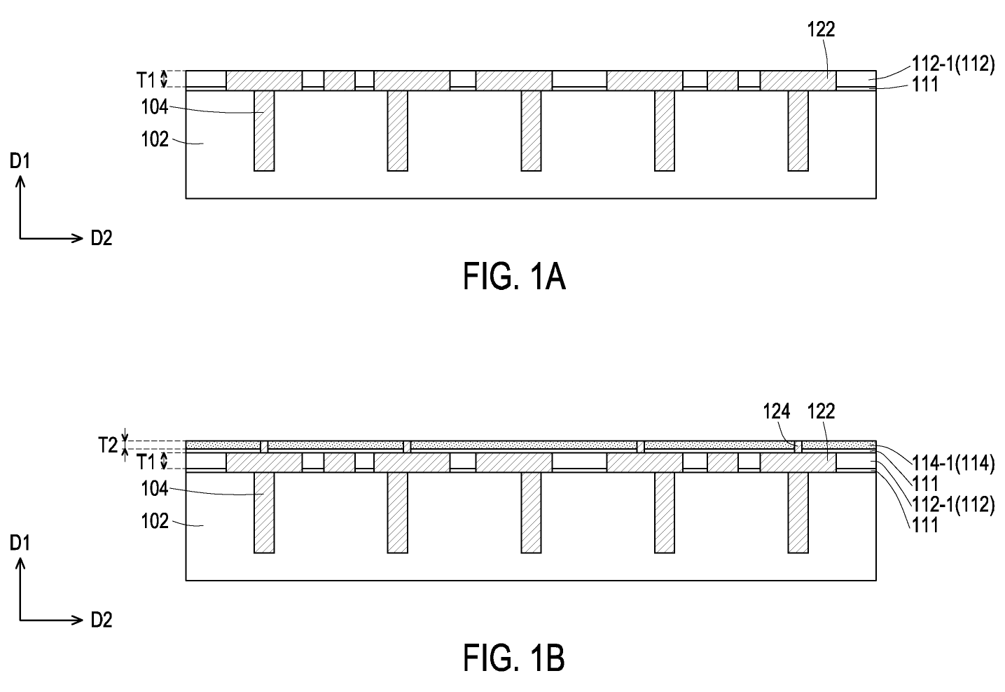

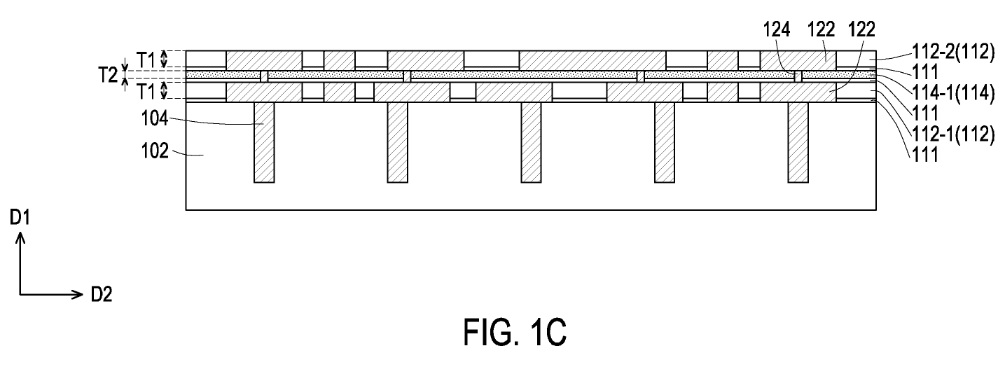

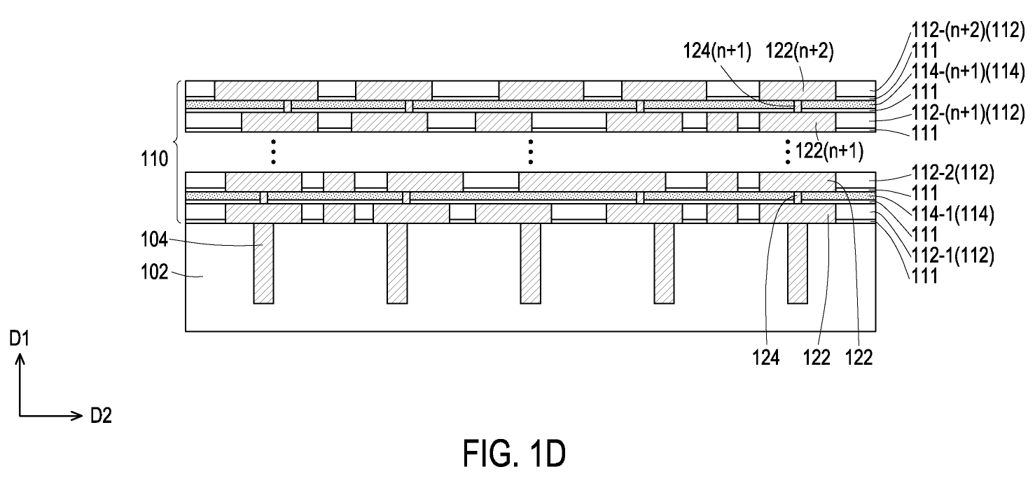

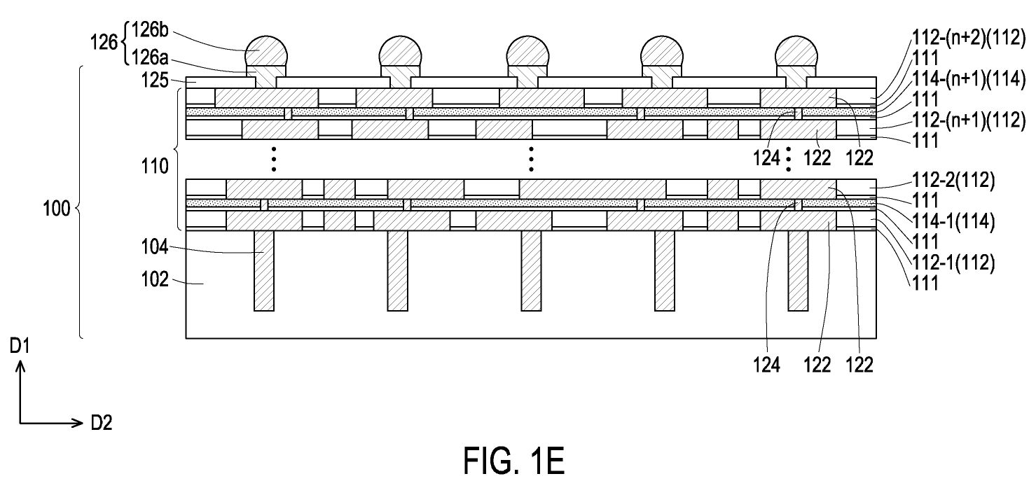

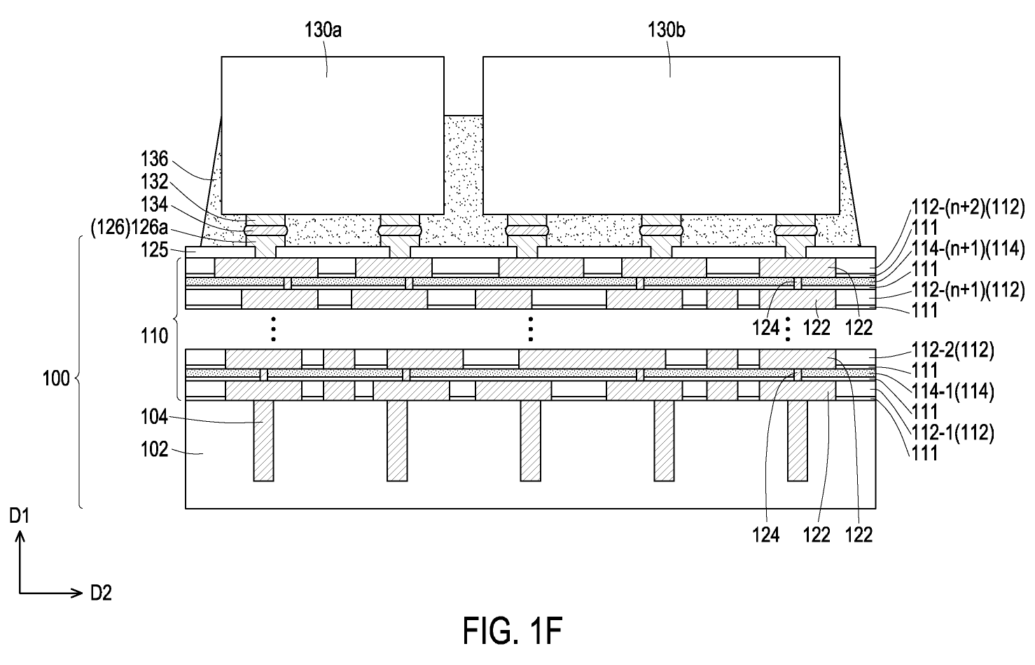

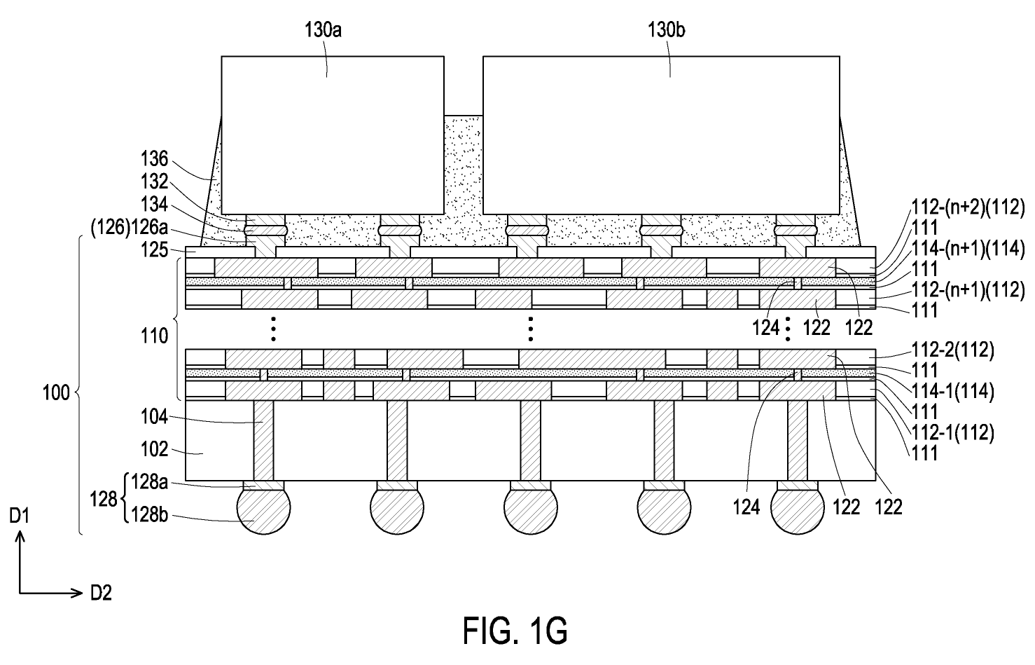

FIG. 1A to FIG. 1G are schematic cross-sectional views of various stages in a method of forming a semiconductor device according to some embodiments.

Referring to FIG. 1A, a substrate 102 is provided. The substrate 102 may be a substrate of doped or undoped silicon. In some embodiments, the substrate 102 include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multi-layered or gradient substrates, may also be used. The substrate 102 includes a package region, for example. In alternative embodiments, the substrate 102 is a wafer substrate and includes a plurality of package regions, which will be singulated in subsequent processing. In some embodiments, the substrate 102 generally does not include active devices therein, although the substrate 102 may include passive devices formed in and/or on a front-side surface of the substrate 102. In alternative embodiments, active devices (e.g., transistors, diodes, etc.), capacitors, resistors, the like, or a combination thereof, are formed in and/or on the front-side surface of the substrate 102.

Then, a plurality of through vias 104 are formed in the substrate 102. The through via 104 may be formed by a single damascene process. A via opening may be first formed in the substrate 102 by, for example, etching, milling, laser techniques, the like, or a combination thereof. A thin barrier material may be conformally deposited in the via opening, such as by CVD, atomic layer deposition (ALD), physical vapor deposition (PVD), thermal oxidation, the like, or a combination thereof. The barrier material may be formed of an oxide, a nitride, a carbide, a combination thereof, or the like. A conductive material may be deposited over the barrier material and in the via opening. The conductive material may be formed by an electro-chemical plating process, CVD, ALD, PVD, the like, or a combination thereof. Examples of the conductive material are copper, tungsten, aluminum, silver, gold, the like, or a combination thereof. Excess conductive material and barrier material is removed from a surface of the substrate 102 by, for example, a CMP. Remaining portions of the barrier material and conductive material form the through via 104.

Then, a dielectric layer 112 (e.g., 112-1) is formed over the substrate 102 and the through vias 104. The dielectric layer 112 (e.g., 112-1) is formed on the substrate 102 along a direction D1 (e.g., z direction), and the dielectric layer 112 (e.g., 112-1) is extended in a direction D2 (e.g., x direction) substantially perpendicular to the direction D1, for example. The dielectric layer 112 (e.g., 112-1) has a thickness T1 in a range of 1 μm to 3 μm, for example. In some embodiments, a material of the dielectric layer 112 (e.g., 112-1) includes undoped silicate glass (USG) or doped silicate glass such as fluorinated silicate glass (FSG), phospho-silicate glass (PSG), boro-silicate glass (BSG), boron-doped phospho-silicate glass (BPSG), silicon oxide, the like, or a combination thereof. A dielectric constant (k) of the dielectric layer 112 (e.g., 112-1) may be in a range of 3.5 to 4.5. For example, the material of the dielectric layer 112 (e.g., 112-1) includes USG or FSG. The dielectric layer 112 (e.g., 112-1) may be deposited by chemical vapor deposition (CVD), physical vapor deposition (PVD), atomic layer deposition (ALD), a spin-on-dielectric (SOD) process, the like, or a combination thereof. The stress of the formed dielectric layer 112 (e.g., 112-1) may be controlled by adjusting RF power (e.g., 100W to 2000W) and/or gas ratio (e.g., a ratio of N₂ to N₂O is in a range of 0.1 to 0.25) of the deposition process such as CVD process. For example, the RF power is increased to increase the stress of the formed dielectric layer 112 (e.g., 112-1), and the ratio of N₂ to N₂O may be lowered to increase the stress of the formed dielectric layer 112 (e.g., 112-1). In some embodiments, an etch stop layer 111 is formed directly below the dielectric layer 112 (e.g., 112-1) and between the substrate 102 and the dielectric layer 112 (e.g., 112-1). The etch stop layer 111 may include a dielectric material, such as, silicon nitride, silicon oxide, silicon oxynitride, or the like, having a different etch rate than the material of the overlying dielectric layer 112 (e.g., 112-1).

After that, a plurality of conductive features 122 (e.g., 122-1) are formed in the dielectric layer 112 (e.g., 112-1). The conductive feature 122 (e.g., 122-1) such as conductive line may be electrically connected to the underlying conductive feature such as through via 104. The conductive feature 122 (e.g., 122-1) may be formed by a single damascene process. A trench opening may be first formed in the dielectric layer 112 (e.g., 112-1) by, for example, etching, milling, laser techniques, the like, or a combination thereof. A thin barrier material may be conformally deposited in the trench opening, such as by CVD, atomic layer deposition (ALD), physical vapor deposition (PVD), thermal oxidation, the like, or a combination thereof. The barrier material may be formed of an oxide, a nitride, a carbide, a combination thereof, or the like. A conductive material may be deposited over the barrier material and in the trench opening. The conductive material may be formed by an electro-chemical plating process, CVD, ALD, PVD, the like, or a combination thereof. Examples of the conductive material are copper, tungsten, aluminum, silver, gold, the like, or a combination thereof. Excess conductive material and barrier material is removed from a surface of the dielectric layer 112 (e.g., 112-1) by, for example, a CMP. Remaining portions of the barrier material and conductive material form the conductive feature 122 (e.g., 122-1). In some embodiments, the conductive feature 122 (e.g., 122-1) includes copper and is a copper line.

In some embodiments, a first surface (e.g., bottom surface) of the conductive feature 122 (e.g., 122-1) is substantially coplanar with a first surface (e.g., bottom surface) of the dielectric layer 112 (e.g., 112-1), and a second surface (e.g., top surface) opposite to the first surface of the conductive feature 122 (e.g., 122-1) is substantially coplanar with a second surface (e.g., top surface) opposite to the first surface of the dielectric layer 112 (e.g., 112-1). Accordingly, the conductive feature 122 (e.g., 122-1) may have a thickness substantially the same as the thickness T1 of the dielectric layer 112 (e.g., 112-1). For example, the thickness of the conductive feature 122 (e.g., 122-1) is in a range of 1 μm to 3 μm. In an embodiment in which the etch stop layer 111 is below the dielectric layer 112 (e.g., 112-1) as shown in FIG. 1A, the first surface (e.g., bottom surface) of the conductive feature 122 (e.g., 122-1) is substantially coplanar with a first surface (e.g., bottom surface) of the etch stop layer 111, and the conductive feature 122 (e.g., 122-1) may have a thickness substantially the same as a total thickness of the thickness T1 of the dielectric layer 112 (e.g., 112-1) and a thickness of the etch stop layer 111.

Referring to FIG. 1B, a dielectric layer 114 (e.g., 114-1) is formed over the dielectric layer 112-1 and the conductive feature 122 (e.g., 122-1). The dielectric layer 114 (e.g., 114-1) may have a thickness T2 less than the thickness T1 of the dielectric layer 112-1. For example, the thickness T2 of the dielectric layer 114 (e.g., 114-1) is in a range of 0.5 μm to 1.5 μm. A material of the dielectric layer 114 (e.g., 114-1) may be different from the material of the dielectric layer 112-1. For example, a dielectric constant (k) of the dielectric layer 114 (e.g., 114-1) is lower than a dielectric constant (k) of the dielectric layer 112-1. A difference between the dielectric constant of the dielectric layer 112-1 and the dielectric layer 114 (e.g., 114-1) is not smaller than 0.5, for example. In some embodiments, the dielectric layer 114 (e.g., 114-1) includes a low-k dielectric material such as a carbon doped oxide or fluorine-silicate-glass (FGS), an extremely low-k dielectric material such as a porous carbon doped silicon dioxide, a polymer such as polyimide, the like, or a combination thereof. The low-k dielectric material may have k values lower than 3.9. In some embodiments, the dielectric layer 114 (e.g., 114-1) has a k value in a range of 2.5 to 3.5. The dielectric layer 114 (e.g., 114-1) may have a stress lower than 100 MPa. The dielectric layer 114 (e.g., 114-1) may be deposited by chemical vapor deposition (CVD), physical vapor deposition (PVD), atomic layer deposition (ALD), a spin-on-dielectric (SOD) process, the like, or a combination thereof. In some embodiments, an etch stop layer 111 is formed directly below the dielectric layer 114 (e.g., 114-1) and between the dielectric layer 112-1 and the dielectric layer 114 (e.g., 114-1). The etch stop layer 111 may include a dielectric material, such as, silicon carbide, silicon nitride, silicon oxide, silicon oxynitride, or the like, having a different etch rate than the material of the overlying dielectric layer 114 (e.g., 114-1).

After that, at least one conductive feature 124 (e.g., 124-1) is formed in the dielectric layer 114 (e.g., 114-1). The conductive feature 124 (e.g., 124-1) such as conductive via may be electrically connected to the underlying conductive feature 122 (e.g., 122-1). For example, the conductive feature 124 (e.g., 124-1) is directly contacting the underlying conductive feature 122 (e.g., 122-1) such as a conductive line. The conductive feature 124 (e.g., 124-1) may be formed by a single damascene process. A via opening may be first formed in the dielectric layer 114 (e.g., 114-1) by, for example, etching, milling, laser techniques, the like, or a combination thereof. A thin barrier material may be conformally deposited in the via opening, such as by CVD, atomic layer deposition (ALD), physical vapor deposition (PVD), thermal oxidation, the like, or a combination thereof. The barrier material may be formed of an oxide, a nitride, a carbide, a combination thereof, or the like. A conductive material may be deposited over the barrier material and in the via opening. The conductive material may be formed by an electro-chemical plating process, CVD, ALD, PVD, the like, or a combination thereof. Examples of the conductive material are copper, tungsten, aluminum, silver, gold, the like, or a combination thereof. Excess conductive material and barrier material is removed from a surface of the dielectric layer 114 (e.g., 114-1) by, for example, a CMP. Remaining portions of the barrier material and conductive material form the conductive feature 124 (e.g., 124-1). In some embodiments, the conductive feature 124 (e.g., 124-1) includes copper and is a copper via.

A first surface (e.g., bottom surface) of the conductive feature 124 (e.g., 124-1) is substantially coplanar with a first surface (e.g., bottom surface) of the dielectric layer 114 (e.g., 114-1), and a second surface (e.g., top surface) opposite to the first surface of the conductive feature 124 (e.g., 124-1) is substantially coplanar with a second surface (e.g., top surface) opposite to the first surface of the dielectric layer 114 (e.g., 114-1), for example. Accordingly, the conductive feature 124 (e.g., 124-1) may have a thickness substantially the same as the thickness T2 of the dielectric layer 114 (e.g., 114-1), and the conductive feature 124 (e.g., 124-1) may have a thickness smaller than the thickness T1 of the conductive feature 122 (e.g., 122-1). For example, the thickness of the conductive feature 124 (e.g., 124-1) in a range of 0.5 μm to 1.5 μm. In an embodiment in which the etch stop layer 111 is below the dielectric layer 114 (e.g., 114-1) as shown in FIG. 1B, the first surface (e.g., bottom surface) of the conductive feature 124 (e.g., 124-1) is substantially coplanar with a first surface (e.g., bottom surface) of the etch stop layer 111, and the conductive feature 124 (e.g., 124-1) may have a thickness substantially the same as a total thickness of the thickness T2 of the dielectric layer 114 (e.g., 114-1) and a thickness of the etch stop layer 111.

Referring to FIG. 1C, a dielectric layer 112 (e.g., 112-2) is formed over the dielectric layer 114 (e.g., 114-1) and the conductive feature 124 (e.g., 124-1). The material, thickness and forming method of the dielectric layer 112-2 are the same as or similar to those of the dielectric layer 112-1. The dielectric layer 112 (e.g., 112-2) may have a thickness T1 larger than the thickness T2 of the dielectric layer 114 (e.g., 114-1). The thickness T1 of the dielectric layers 112 (e.g., 112-1 and 112-2) may be the same or different. The material of the dielectric layers 112 (e.g., 112-1 and 112-2) may be the same or different. The material of the dielectric layer 112 (e.g., 112-1 and 112-2) is different from the material of the dielectric layer 114 (e.g., 114-1). The dielectric constant (k) of the dielectric layer 112 (e.g., 112-1 and 112-2) may be larger than the dielectric constant (k) of the dielectric layer 114 (e.g., 114-1). A difference between the dielectric constant (k) of the dielectric layer 112 (e.g., 112-1 and 112-2) and the dielectric layer 114 (e.g., 114-1) is not smaller than 0.5, for example. The dielectric constant (k) of the dielectric layer 112 (e.g., 112-1 and 112-2) may be in a range of 3.5 to 4.5. For example, the material of the dielectric layer 112 (e.g., 112-1 and 112-2) includes USG or FSG, and the dielectric layer 114 (e.g., 114-1) includes low-k dielectric material. In some embodiments, an etch stop layer 111 is formed directly below the dielectric layer 112 (e.g., 112-2). The etch stop layer 111 may include a dielectric material, such as, silicon nitride, silicon oxide, silicon oxynitride, or the like, having a different etch rate than the material of the overlying dielectric layer 112 (e.g., 112-2).

After that, a plurality of conductive features 122 (e.g., 122-2) are formed in the dielectric layer 112 (e.g., 112-2). The conductive feature 122 (e.g., 122-2) such as conductive line may be electrically connected to the underlying conductive feature 124 (e.g., 124-1) such as conductive via. The conductive feature 122 (e.g., 122-2) may be formed by a single damascene process, and the formation method is similar to or the same as that of the conductive feature 122-1. In alternative embodiments, the conductive feature 122 (e.g., 122-2) and the underlying conductive feature 124 (e.g., 124-1) are formed by a same process such as a dual damascene process. For example, the conductive feature 122 (e.g., 122-2) and the underlying conductive feature 124 (e.g., 124-1) are formed by forming a via opening in the dielectric layer 114 (e.g., 114-1) and a trench opening in the dielectric layer 112 (e.g., 112-2) and connecting to the via opening, depositing a barrier material and a conductive material into the via opening and trench opening and removing excess conductive material and barrier material outside the via opening and trench opening. In some embodiments, the conductive feature 122 (e.g., 122-2) includes copper and is a copper line.

In some embodiments, a first surface (e.g., bottom surface) of the conductive feature 122 (e.g., 122-2) is substantially coplanar with a first surface (e.g., bottom surface) of the dielectric layer 112 (e.g., 112-2), and a second surface (e.g., top surface) opposite to the first surface of the conductive feature 122 (e.g., 122-2) is substantially coplanar with a second surface (e.g., top surface) opposite to the first surface of the dielectric layer 112 (e.g., 112-2). Accordingly, the conductive feature 122 (e.g., 122-2) may have a thickness substantially the same as the thickness T1 of the dielectric layer 112 (e.g., 112-2). For example, the thickness of the conductive feature 122 (e.g., 122-2) is in a range of 1 μm to 3 μm. In an embodiment in which the etch stop layer 111 is below the dielectric layer 112 (e.g., 112-2) as shown in FIG. 1C, the first surface (e.g., bottom surface) of the conductive feature 122 (e.g., 122-2) is substantially coplanar with a first surface (e.g., bottom surface) of the etch stop layer 111, and the conductive feature 122 (e.g., 122-2) may have a thickness substantially the same as a total thickness of the thickness T1 of the dielectric layer 112 (e.g., 112-2) and a thickness of the etch stop layer 111.

Referring to FIG. 1D, in some embodiments, after the dielectric layers 112-1, 114-1, 112-2 and the conductive features 122-1, 124-1, 122-2 are formed, dielectric layers 114-2 (not shown), 112-3 (not shown)…112-(n+1), 114-(n+1), 112-(n+2) and conductive features 124-2 (not shown), 122-3 (not shown)…122-(n+1), 124-(n+1), 122-(n+2) therein may be sequentially formed over the dielectric layer 112-2. Thus, the formation of an interconnect structure 110 of the interposer 100 may be completed. The dielectric layers 114-2 (not shown), 112-3 (not shown)…112-(n+1), 114-(n+1), 112-(n+2) and the conductive features 124-2 (not shown), 122-3 (not shown)…122-(n+1), 124-(n+1), 122-(n+2) may be formed by the same or similar process as described with reference to FIG. 1A to FIG. 1C. That is, the dielectric layer 114 may be formed by the process of FIG. 1B, and the dielectric layer 112 may be formed by the process of FIG. 1A or FIG. 1C.

In some embodiments, the interconnect structure 110 may include a metal one interconnect layer (M1 level), a via one interconnect layer (V1 level), a metal two interconnect layer (M2 level), a via two interconnect layer (V2 level), a metal three interconnect layer (M3 level)…a metal (n+1) interconnect layer (M(n+1) level), a via (n+1) interconnect layer (V(n+1) level) and a metal (n+2) interconnect layer (M(n+2) level). However, the disclosure is not limited thereto. Each of the M1 level, V1 Level, M2 level, V2 level, M3 level...M(n+ 1) level, V(n+1) level and M(n+2) level may be referred to as a metal level. The conductive features 122-1 formed at the M1 level may be referred to as M1 metal lines. Similarly, the conductive features 122 or 124 formed at the V1 level, M2 level, V2 level, M3 level ...M(n+ 1) level, V(n+1) level and M(n+2) level may be referred to as M1 metal lines, V1 vias, M2 metal lines, V2 vias, M3 metal lines…M(n+1) metal lines, V(n+1) vias, and M(n+2) metal lines, respectively. In some embodiments, n represents a positive integer, and a total number of the interconnect layers is 2n+3. In some embodiments, the conductive features 122 at a same level are formed simultaneously. In some embodiments, conductive features 122 or 124 at a same level have top surfaces that are substantially planar with one another and/or bottom surfaces that are substantially planar with one another. In some embodiments, the conductive via 124 has a vertical sidewall. However, the disclosure is not limited thereto. The conductive via 124 may have substantially vertical sidewall or an inclined sidewall. It is noted that the interconnect structure 110 may have any suitable number of interconnection layers, and at least two dielectric layers 114, 112 (e.g., dielectric layers 114-(n+1), 112-(n+2)) are formed by the processes depicted in FIG. 1A to FIG. 1C. In some embodiments, since the dielectric layer 114 is disposed between the dielectric layers 112, and separates the conductive features 122 in adjacent two dielectric layers 112, the dielectric layer 114 may be also referred to as an intermetal dielectric layer.

Referring to FIG. 1E, after the interconnect structure 110 is formed, conductive connectors 126 are formed on and electrically connected to the interconnect structure 110 to provide an external electrical connection. In some embodiments, the conductive connectors 126 are ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 126 are formed in and/or on a dielectric layer 125 over the interconnect structure 110, for example. A material of the dielectric layer 125 includes polyimide, epoxy resin, acrylic resin, phenol resin, benzocyclobutene (BCB), polybenzooxazole (PBO), oxides, nitrides, the like, or any other suitable dielectric material.

For example, the conductive connectors 126 include underbump metallizations (UBMs) 126a and solder regions 126b over the UBMs 126a. The UBMs 126a may be conductive pillars, pads, or the like. In some embodiments, the UBMs 126a may be formed by forming a seed layer over the interconnect structure 110. The seed layer may be a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 126a. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, nickel, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 126a.

In some embodiments, the UBMs 126a includes three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the UBMs 126a. Any suitable materials or layers of material that may be used for the UBMs 126a are fully intended to be included within the scope of the current application.

The solder regions 126b may include a solder material and may be formed over the UBMs 126a by dipping, printing, plating, or the like. The solder material may include, for example, lead-based and lead-free solders, such as Pb-Sn compositions for lead-based solder; lead-free solders including InSb; tin, silver, and copper (SAC) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 305, and SAC 405, as examples. Lead-free solders may further include SnCu compounds as well, without the use of silver (Ag). Lead-free solders may also include tin and silver, Sn-Ag, without the use of copper. In some embodiments, a reflow process may be performed, giving the solder regions 126b a shape of a partial sphere in some embodiments. In alternative embodiments, the solder regions 126b may have other shapes, such as non-spherical shapes.

Referring to FIG. 1G, a plurality of integrated circuits 130a, 130b are bonded to the interposer 100. For example, the integrated circuits 130a, 130b are stacked on the interposer 100 along the direction D1 (e.g., z direction), and the integrated circuits 130a, 130b and the interposer 100 are respectively extended in the direction D2. In some embodiments, the direction D1 is also referred to a stacking direction of the integrated circuit 130a, 130b and the interposer 100.

The integrated circuits 130a, 130b are the same or different. Each integrated circuit 130a, 130b may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or a combination thereof. The integrated circuit 130a, 130b may be a stacked device that includes multiple semiconductor substrates (not shown). For example, the integrated circuit 130a, 130b may be a memory device that includes multiple memory dies such as a hybrid memory cube (HMC) device, a high bandwidth memory (HBM) device, or the like. In such embodiments, the integrated circuit 130a, 130b includes multiple semiconductor substrates interconnected by through-substrate vias (TSVs) such as through-silicon vias (not shown). Each of the semiconductor substrates may (or may not) have a separate interconnect structure. The integrated circuit 130a, 130b may have high bandwidth, I/O count and/or high speed requirements. In some embodiments, the integrated circuits 130a, 130b are SoC and HBM device.

In some embodiments, the integrated circuits 130a, 130b have different or the same sizes (e.g., different heights and/or surface areas). For example, the integrated circuits 130a, 130b have different width along the direction D2. In some embodiments, the integrated circuits 130a, 130b have the same height or different height along the direction D1.

The integrated circuit 130a, 130b may include a semiconductor substrate (not shown), a device layer (not shown) and an interconnect structure (not shown). The semiconductor substrate may be a substrate of silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multi-layered or gradient substrates, may also be used.

The device layer may include active devices (e.g., transistors, diodes, etc.), capacitors, resistors, the like, or a combination thereof and an inter-layer dielectric (ILD) surrounding and covering the devices. The ILD may include one or more dielectric layers formed of materials such as phospho-silicate glass (PSG), boro-silicate glass (BSG), boron-doped phospho-silicate glass (BPSG), undoped silicate glass (USG), or the like. Conductive plugs (not separately illustrated) may extend through the ILD to electrically and physically couple the devices. For example, when the devices are transistors, the conductive plugs couple the gates and source and drain regions of the transistors. The conductive plugs may be formed of tungsten, cobalt, nickel, copper, silver, gold, aluminum, the like, or a combination thereof.

The interconnect structure is over the device layer, and is used to electrically connect the devices of the semiconductor substrate. The interconnect structure may be over the ILD and the conductive plugs. The interconnect structure may include one or more dielectric layer(s) and respective metallization layer(s) in the dielectric layer(s). Acceptable dielectric materials for the dielectric layers include low-k dielectric materials such as PSG, BSG, BPSG, USG, or the like. Acceptable dielectric materials for the dielectric layers further include oxides such as silicon oxide or aluminum oxide; nitrides such as silicon nitride; carbides such as silicon carbide; the like; or a combination thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layers may include conductive vias and/or conductive lines to interconnect the devices of the semiconductor substrate. The metallization layers may be formed of a conductive material, such as a metal, such as copper, cobalt, aluminum, gold, a combination thereof, or the like. The interconnect structure may be formed by a damascene process, such as a single damascene process, a dual damascene process, or the like.

In some embodiments, the integrated circuits 130a, 130b include a plurality of conductive connectors 132 at the outermost surfaces (e.g., bottom surfaces). The conductive connectors 132 are similar to the conductive connectors 126 described above, and the description is not repeated herein. In the illustrated embodiment, the conductive connectors 132 include UBMs and solder regions over the UBMs. However, the conductive connectors 132 may have other suitable configurations. In some embodiments, the conductive connectors 132 are in physical contact with respective conductive connectors 126 of the interposer 100, such that the solder regions 126b of the conductive connectors 126 are in physical contact with the respective conductive connectors 132 and form the solder joints 134 therebetween. The solder joints 134 electrically and mechanically couple the integrated circuits 130a, 130b to the interposer 100.

In some embodiments, an underfill 136 is formed around the solder joints 134, and in a gap between the integrated circuits 130a, 130b and the interposer 100. The underfill 136 may reduce stress and protect the solder joints 134. The underfill 136 may be formed of an underfill material such as a molding compound, epoxy, or the like. The underfill 136 may be formed by a capillary flow process after the integrated circuits 130a, 130b are attached to the interposer 100, or may be formed by a suitable deposition method before the integrated circuits 130a, 130b are attached to the interposer 100. The underfill 136 may be applied in liquid or semi-liquid form and then subsequently cured. In some embodiments, the underfill 136 extends along sidewalls of the integrated circuits 130a, 130b. However, the disclosure is not limited thereto. In alternative embodiments, the underfill 136 is omitted. In some embodiments, a surface (e.g., top surface) of the underfill 136 is lower than the surfaces (e.g., top surfaces) of the integrated circuits 130a, 130b. However, the disclosure is not limited thereto. In alternative embodiments, the surface (e.g., top surface) of the underfill 136 is substantially coplanar with the surfaces (e.g., top surfaces) of the integrated circuits 130a, 130b.

Referring to FIG. 1G, the substrate 102 of the interposer 100 is thinned to expose the conductive vias 104. Exposure of the conductive vias 104 may be accomplished by a thinning process, such as a grinding process, a CMP, an etch-back, a combination thereof, or the like. In some embodiments, the thinning process for exposing the conductive vias 104 includes a CMP. Subsequently, conductive connectors 128 are formed on the exposed surface of the interposer 100 as the conductive connectors 126 described above with reference to FIG. 1E, and the description is not repeated herein. In the illustrated embodiment, the conductive connectors 128 comprise UBMs 128a, and solder regions 128b over the UBMs 128a. The UBMs 128a and the solder regions 128b may be formed using similar material and methods as the UBMs 126a and the solder regions 126b, respectively, described above with reference to FIG. 1E, and the description is not repeated herein. In alternative embodiments, an encapsulant is further formed to encapsulate the integrated circuits 130a, 130b and the underfill 136. In alternative embodiments in which the interposer wafer is provided, a singulation process is performed after forming the conductive connectors 128. The singulation process is performed on the package component by cutting along scribe line regions, e.g., around the package region. The singulation process may include sawing, etching, dicing, the like, or a combination thereof. In such embodiments, the singulation process includes sawing the interconnect structure 110 and the substrate 102. The singulation process singulates the package region from adjacent package regions to form a singulated semiconductor device as illustrated in FIG. 1G. The singulated semiconductor device is from the package region. The singulation process forms interposers 110 from the singulated portions of the interposer wafer. Furthermore, the formed semiconductor device as illustrated in FIG. 1G may be bonded to another circuit substrate through the conductive connectors 128 of the interposer 100.

In some embodiments, the interposer 100 has composite dielectrics including the dielectric layer 112 and the dielectric layer 114. Since the dielectric layer 114 may have larger thickness and low k, the parasitic capacitance (e.g., intra-layer parasitic capacitance) formed between the conductive features (e.g., conductive feature 122-1 and conductive feature 122-2) may be reduced and cross-talk may be lowered. Furthermore, the thick conductive feature 122 may provide low resistance. Accordingly, the interconnection structure 110 of the interposer 100 may have low parasitic capacitance, reduced effective dielectric constant and low resistance, and thus may provide low insertion loss and improved signal integrity and/or electrical performance for the integrated circuits 130a, 130b such as HBM and SoC. Thus, the interposer is suitable for the semiconductor device such as HPC (high performance computing) device which requires high speed and/or frequency electrical performance application in 3DIC. Furthermore, the stress may be adjusted by the dielectric layers 112, and thus the warpage caused by the interposer may be also prevented, and thus a reliable semiconductor device such as package structure may be obtained.

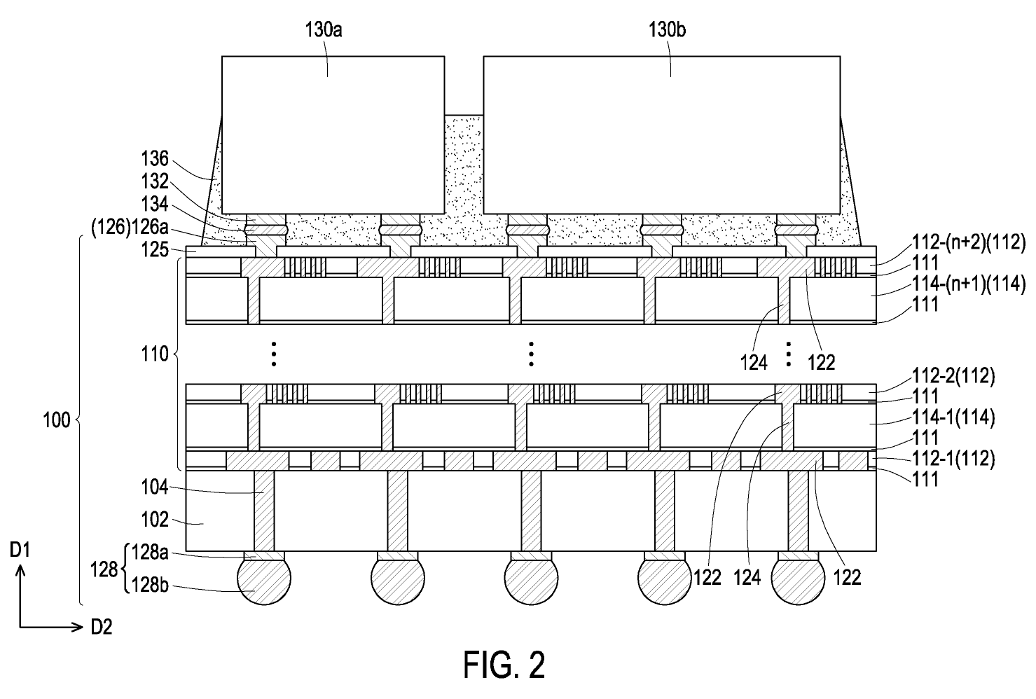

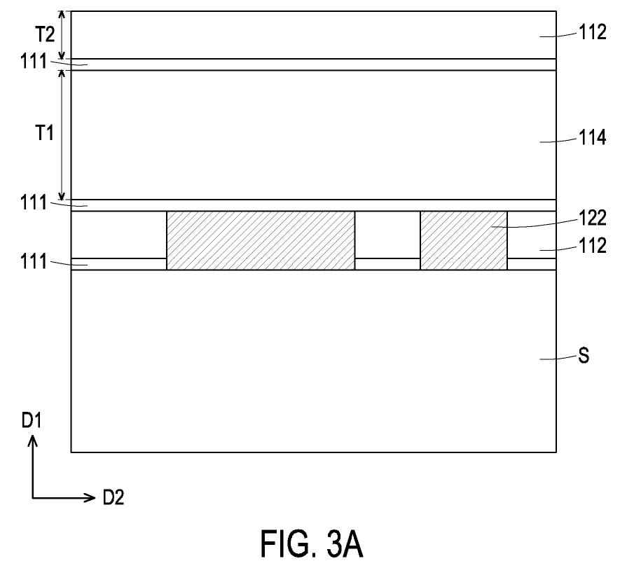

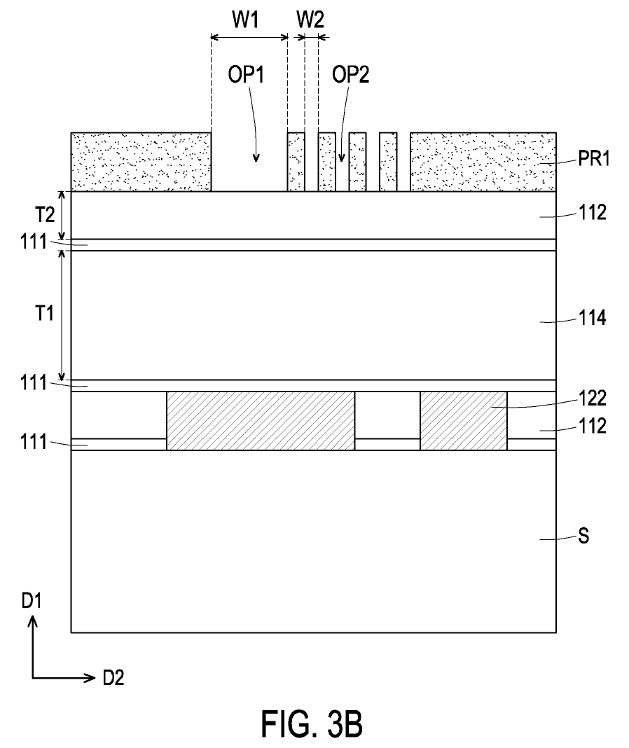

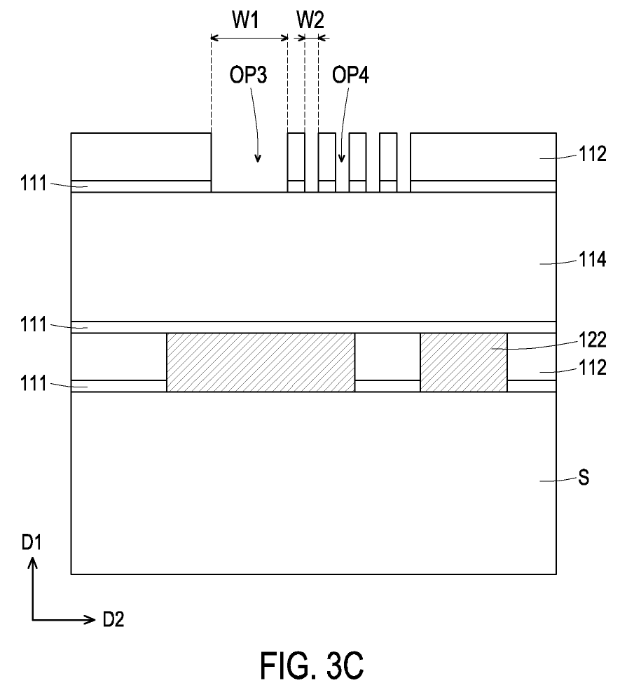

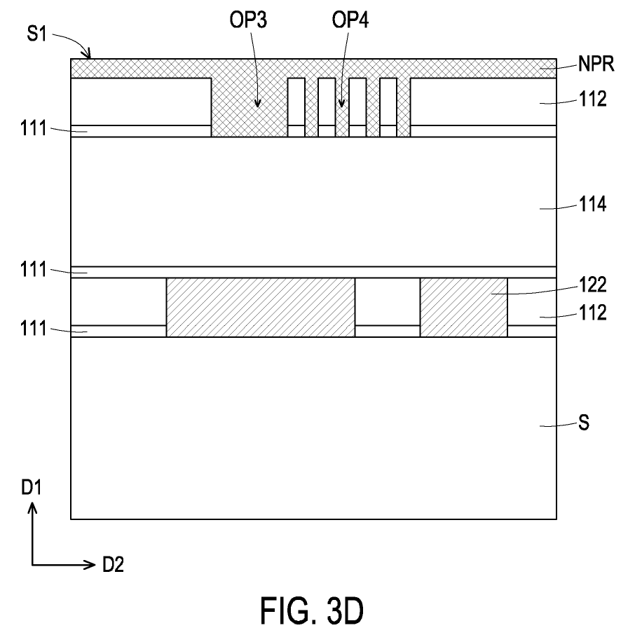

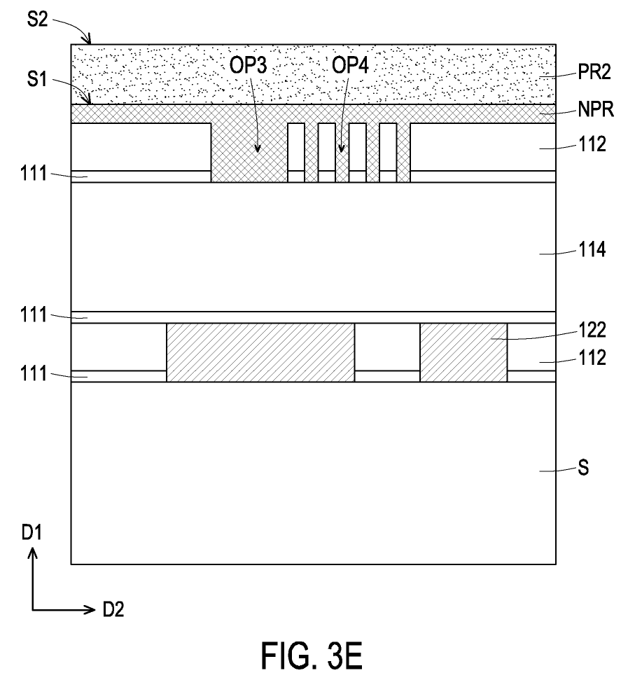

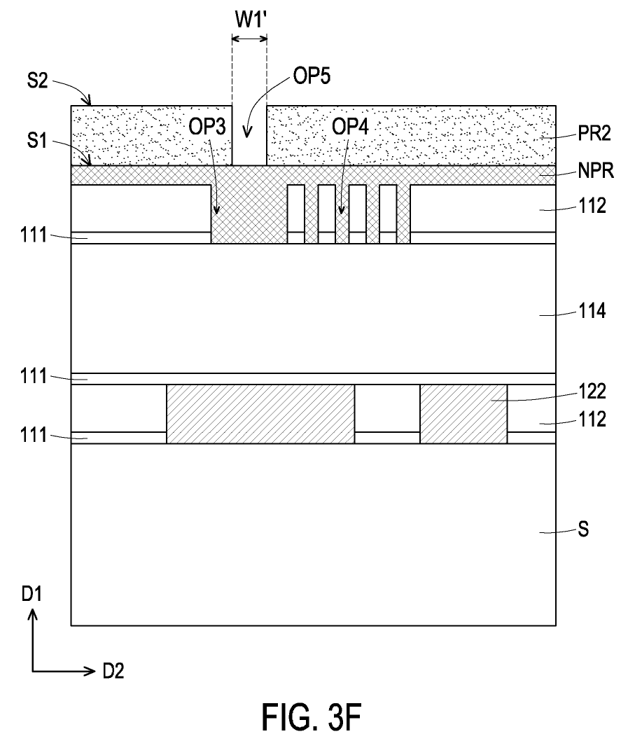

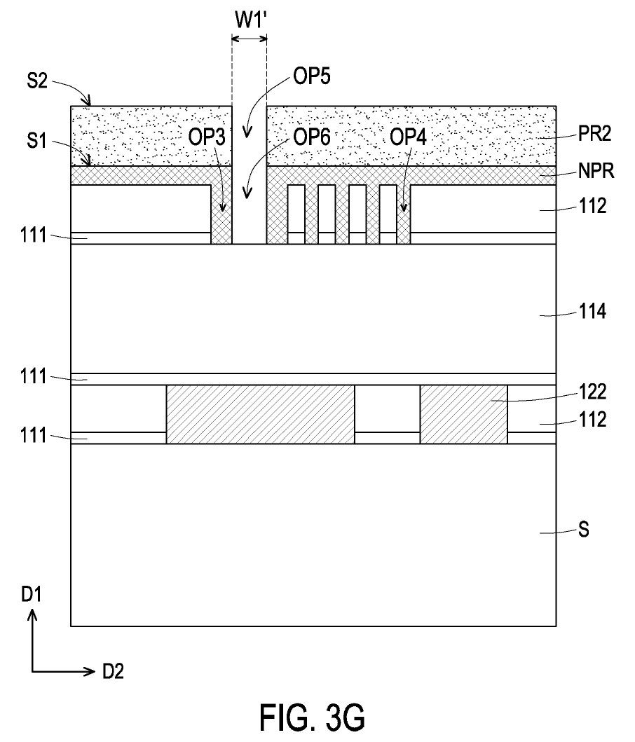

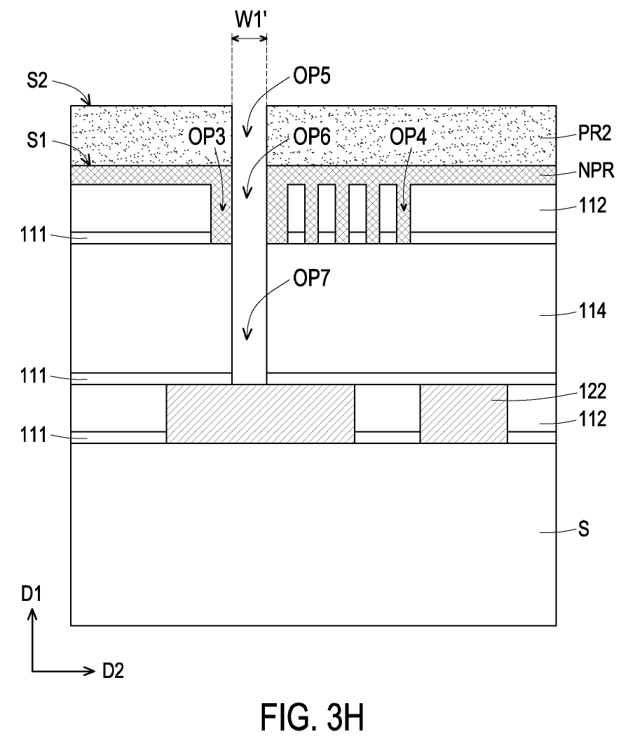

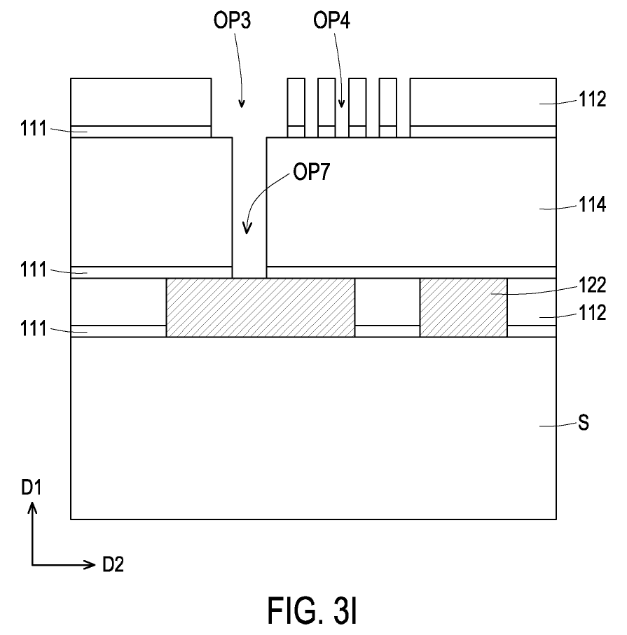

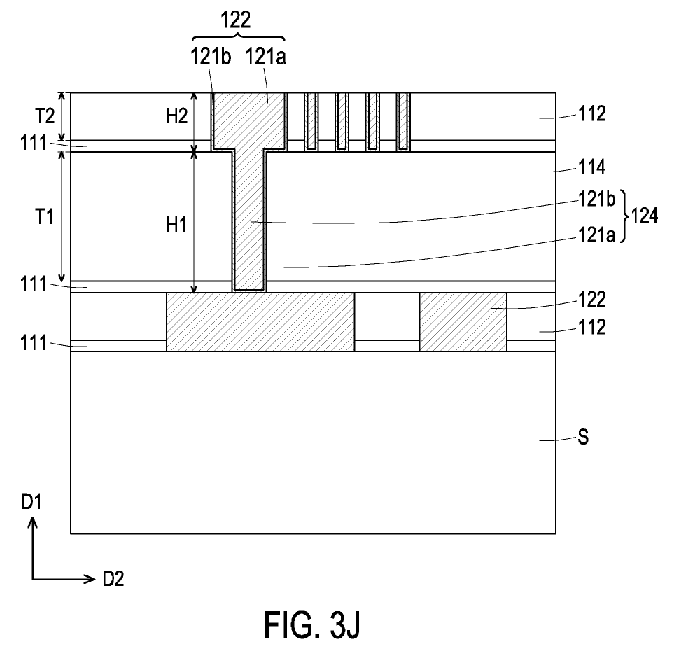

FIG. 2 is a schematic cross-sectional view of a semiconductor device according to some embodiments. The semiconductor device of FIG. 2 is similar to the semiconductor device of FIG. 1G, and the difference lies in the formation of the interconnect structure 110 of the interposer 100. In some embodiments, at least one dielectric layer 114 (e.g., 114-1…114-(n+1)) and the overlying dielectric layer 112 (e.g., 112-2…112-(n+2)) and the respective conductive features 124, 122 therein may be formed by a method illustrated in FIG. 3A to FIG. 3J.

Referring to FIG. 3A, a dielectric layer 112 is provided over a structure S, and a plurality of conductive features 122 are formed in the dielectric layer 112. The structure S may be the substrate 102 or any dielectric layer 114 of FIG. 2. In other words, the dielectric layer 112 may be any one of dielectric layers 112 of FIG. 2. Then, a dielectric layer 114 is formed on the dielectric layer 112 along a direction D1 (e.g., z direction), and a dielectric layer 112 is formed on the dielectric layer 114. The dielectric layer 114 and the overlying dielectric layer 112 may be any two immediately adjacent dielectric layers 114, 112 (e.g., 114-1 and 112-2…or 114-(n+1) and 112-(n+2)) of FIG. 2. In some embodiments, a material of the dielectric layers 112, 114 includes undoped silicate glass (USG) or doped silicate glass such as fluorinated silicate glass (FSG), phospho-silicate glass (PSG), boro-silicate glass (BSG), boron-doped phospho-silicate glass (BPSG), silicon oxide, the like, or a combination thereof. The dielectric layers 112, 114 may be deposited by chemical vapor deposition (CVD), physical vapor deposition (PVD), atomic layer deposition (ALD), a spin-on-dielectric (SOD) process, the like, or a combination thereof. The materials and forming methods of the conductive features 122 may be similar to those described with reference to FIG. 1A, so the detailed descriptions thereof are omitted herein. In some embodiments, an etch stop layer 111 is respectively formed directly below the dielectric layers 112, 114. The materials and forming methods of the etch stop layer 111 are similar to those described with reference to FIG. 1A, so the detailed descriptions thereof are omitted herein. In some embodiments, the dielectric layer 114 has a thickness T1 larger than a thickness T2 of the overlying dielectric layer 112. A ratio of the thickness T1 to the thickness T2 may be larger than 1.25. For example, the thickness T1 is in a range of 2.5 μm to 3 μm, and the thickness T2 is in a range of 0.5 μm to 1.5 μm.

Referring to FIG. 3B, a patterned photoresist PR1 is formed on the dielectric layer 112. First, a photoresist (not shown) may be formed on the dielectric layer 112 by spin coating or the like. The photoresist may be a photosensitive material, which includes organic materials, and may be a positive photosensitive material or a negative photosensitive material. Then, the photoresist may be exposed to light for patterning, to form the patterned photoresist PR1. In some embodiments, the patterned photoresist PR1 includes at least one opening such as openings OP1, OP2. In some embodiments, the opening OP1 has a width larger than a width of each of the openings OP2.

Referring to FIG. 3C, by using the patterned photoresist PR1 as a mask, at least one opening such as openings OP3, OP4 are formed in the dielectric layer 112. The openings OP3, OP4 may be formed by removing portions of the dielectric layer 112 and the etch stop layer 111 therebelow. The removal method may include an etch process such as a dry etch process or a wet etch process. In some embodiments, the opening OP3 has a width W1 along a direction D2 (e.g., x direction) than a width W2 of each of the openings OP4. An aspect ratio of the opening OP3 is in a range of 2.5 to 4.5, for example. The opening OP3 may be also referred to as a trench opening. The width W2 of the openings OP4 may be substantially the same or different. The opening OP3 is directly above the conductive feature 122 in the underlying dielectric layer 112, and the openings OP4 are disposed adjacent to the opening OP3, for example. After formation of the openings OP3, OP4 in the dielectric layer 112, the patterned photoresist PR1 may be removed by an acceptable ashing or stripping process, such as using an oxygen plasma or the like.

Referring to FIG. 3D, a non-photosensitive material NPR is formed on the dielectric layer 112, to fill up the openings OP3, OP4. The non-photosensitive material NPR may be blanket formed over the dielectric layer 112 and completely fill the openings OP3, OP4 of the dielectric layer 112. A material of the non-photosensitive material NPM includes a polymer such as amorphous carbon and is formed by coating such as spin-coating or the like, for example. The non-photosensitive material NPM may also be a bottom anti-reflective coating (BARC) layer or an ashing removal dielectric (ARD) layer (such as amorphous carbon). The non-photosensitive material NPM on the dielectric layer 112 may have a thickness in a range of 1 μm to 1.5 μm. In some embodiments, after forming the non-photosensitive material NPR, a planarization process such as chemical mechanical planarization (CMP) process may be performed to planarize a surface (e.g., top surface) S1 of the non-photosensitive material NPR. After the planarization process, the non-photosensitive material NPR may have a substantially flat surface S1. For example, the surface S1 of the non-photosensitive material NPR has a good uniformity. In some embodiments, the non-photosensitive material NPR is also referred to as a non-photosensitive resist.

Referring to FIG. 3E, a photoresist PR2 is formed on the non-photosensitive material NPR. The photoresist PR2 may be a photosensitive material, which includes organic materials, and may be a positive photosensitive material or a negative photosensitive material. The photoresist PR2 may be formed by spin coating or the like. In some embodiments, since the non-photosensitive material NPR has a substantially flat surface S1, the photoresist PR2 formed thereon also has a substantially flat surface S2. On contrary, in an embodiment in which the photoresist PR2 is directly formed on the dielectric layer 112 including the openings OP3, OP4 therein, the surface S2 of the photoresist PR2 may have a poor uniformity due to the loading effect, which would affect the subsequent patterning process to the dielectric layer 112.

Referring to FIG. 3F, the photoresist PR2 is patterned, to form an opening OP5. The patterning process includes exposure and developing processes. In some embodiments, the opening OP5 of the photoresist PR2 exposes the photosensitive material NPR in the opening OP3 while the photosensitive material NPR in the opening OP4 is covered by the photoresist PR2. The opening OP5 may be directly on the opening OP3, and also directly on the conductive feature 122 in the underlying dielectric layer 112. For example, a middle line of the opening OP5 is substantially overlapped with a middle line of the opening OP3. The opening OP5 may have a width W1’ smaller than the width W1 of the opening OP3, and the width W1’ of the opening OP5 may be substantially equal to a desired width W1’ of the conductive feature 124 (as shown in FIG. 3J) to be formed.

Referring to FIG. 3G, by using the photoresist PR2 as a mask, a portion of the non-photosensitive material NPR is removed, to form an opening OP6 in the non-photosensitive material NPR. The removal method may include an exposure process and an etch process such as a dry etch process or a wet etch process. In some embodiments, the portion of the non-photosensitive material NPR exposed by the opening OP5 is removed to form the opening OP6, and the opening OP6 exposes the underlying dielectric layer 114. As shown in FIG. 3G, the opening OP6 is disposed in the non-photosensitive material NPR within the opening OP3, and the opening OP6 has a width W1’ smaller than the width W1 of the opening OP3.

Referring to FIG. 3H, by using the non-photosensitive material NPR having the opening OP6 as a mask, a portion of the dielectric layer 114 is removed to form an opening OP7. In some embodiments, the opening OP7 is formed by removing the portion of the dielectric layer 114 and the underlying etch stop layer 111 with an etch process such as a try etch process or a wet etch process. The opening OP7 may expose the underlying conductive feature 122 in the underlying dielectric layer 112. The opening OP7 has a width W1’ corresponding to the width W1’ of the opening OP6, for example.

Referring to FIG. 3I, the remained photoresist PR2 and the remained non-photosensitive material NPR are removed. For example, the non-photosensitive material NPR remained in the openings OP3, OP4 and the photoresist PR2 remained on the non-photosensitive material NPR are entirely removed. The non-photosensitive material NPR and the photoresist PR2 may be removed by an acceptable ashing or stripping process, such as using an oxygen plasma or the like. The non-photosensitive material NPR and the photoresist PR2 may be removed simultaneously by a same process. After removing, the opening OP7 is disposed in the dielectric layer 114 and the openings OP3, OP4 are disposed in the dielectric layer 112. In some embodiments, the opening OP7 is a via opening, and the opening OP3 is a trench opening and connects to the opening OP7. The width W1 of the opening OP3 is larger than the width W1’ of the opening OP7.

Referring to FIG. 3J, a conductive feature 124 is formed in the opening OP7, and a conductive feature 122 is formed in the opening OP3. In some embodiments, the conductive feature 122 and the underlying conductive feature 124 are formed by a same process such as a dual damascene process. For example, a barrier material is formed on sidewalls and bottom surfaces of the openings OP3, OP7 and a conductive material is then formed to fill up the openings OP3, OP7. After that, excess conductive material and barrier material outside the openings OP3, OP7 may be removed by a planarization process such as CMP, to form the conductive feature 124 in the opening OP7, and the conductive feature 122 in the opening OP3. The conductive feature 124 (e.g., conductive via) is in direct contact with the overlying conductive feature 122 (e.g., conductive line) and the underlying conductive feature 122 (e.g., conductive line), for example. In some embodiments, the conductive feature 124 and the conductive feature 122 respectively include a conductive layer 121a and a barrier layer 121b surrounding the conductive layer 121a. A surface (e.g., top surface) of the conductive feature 122 is substantially coplanar with a surface (e.g., top surface) of the dielectric layer 112. For example, surfaces (e.g., top surfaces) of the conductive layer 121a and the barrier layer 121b are substantially coplanar with a surface (e.g., top surface) of the dielectric layer 112. A height H1 of the conductive feature 124 is substantially equal to the thickness T1 of the dielectric layer 114 (e.g., a total thickness of the dielectric layer 114 and the etch stop layer 111 therebelow), and a height H2 of the overlying conductive feature 122 is substantially equal to the thickness T2 of the overlying dielectric layer 112 (e.g., a total thickness of the dielectric layer 112 and the etch stop layer 111 therebelow), for example. In some embodiments, a ratio of the height H1 of the conductive feature 124 to the height H2 of the overlying conductive feature 122 may be larger than 1.25. It is noted that the conductive feature 124 and the overlying conductive feature 122 (also the dielectric layer 114 and the overlying dielectric layer 112) may be disposed in any suitable location of the interconnect structure 110 of the interposer 100 in FIG. 2.

In some embodiments, the thickness T1 of the dielectric layer 114 is larger than the thickness T2 of the overlying dielectric layer 112. Thus, a ratio of the height H1 of the conductive feature 124 in the dielectric layer 114 to the height H2 of the overlying conductive feature 122 may be high. Since the dielectric layer 114 may have a larger thickness, the parasitic capacitance (e.g., intra-layer parasitic capacitance) formed between the conductive features 122 (e.g., conductive feature 122-1 and conductive feature 122-2) may be reduced. Accordingly, the interposer 100 may provide low insertion loss and improved signal integrity and/or electrical performance for the integrated circuits 130a, 130b such as HBM and SoC (system on integrated circuit). Accordingly, the interposer is suitable for the semiconductor device such as HPC device which requires high speed and/or frequency electrical performance application in 3DIC. Furthermore, the warpage caused by the interposer may be also prevented, and thus a reliable semiconductor device such as package structure may be obtained.

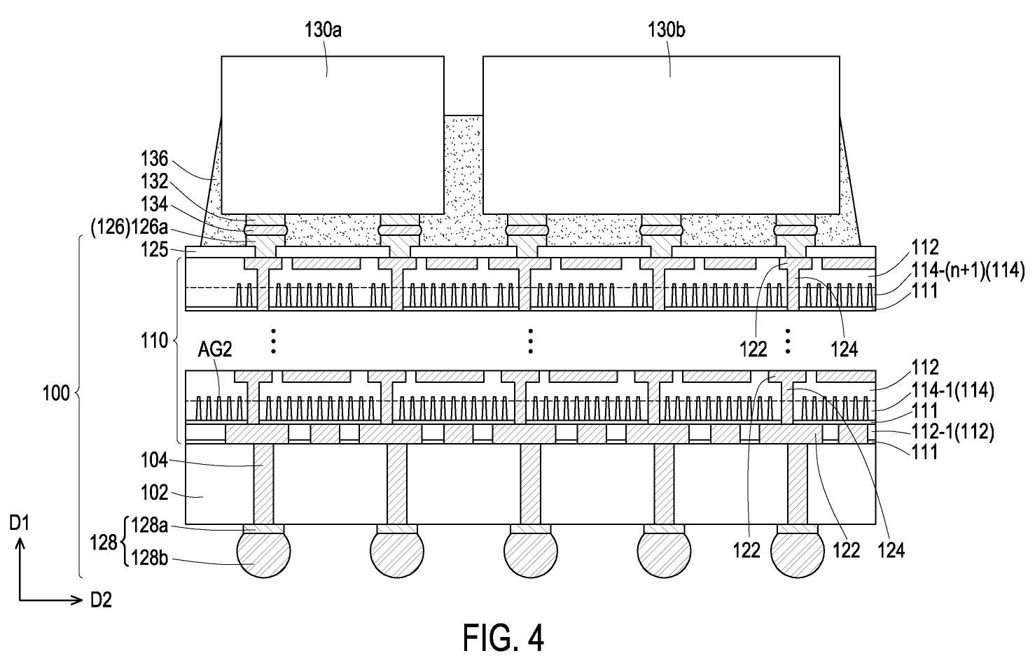

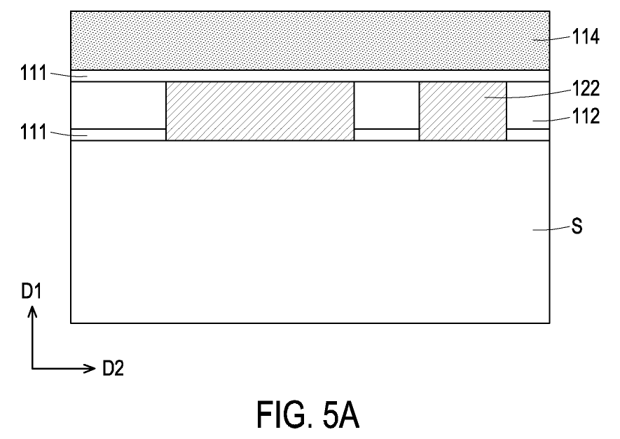

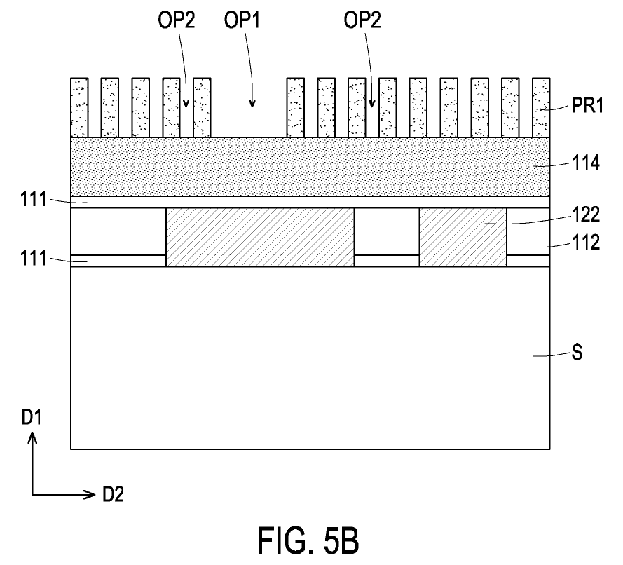

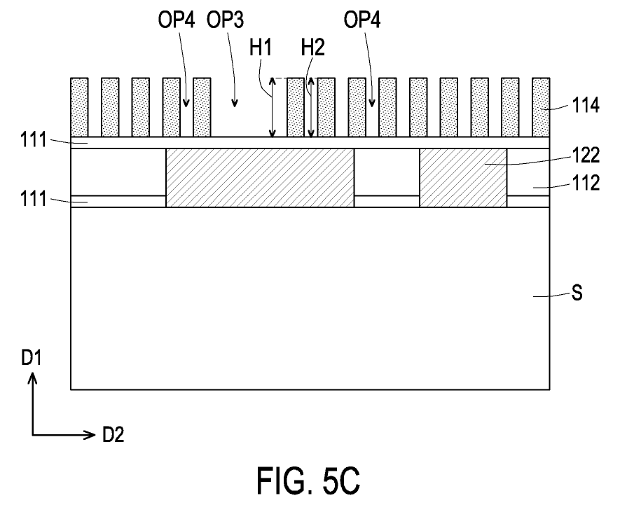

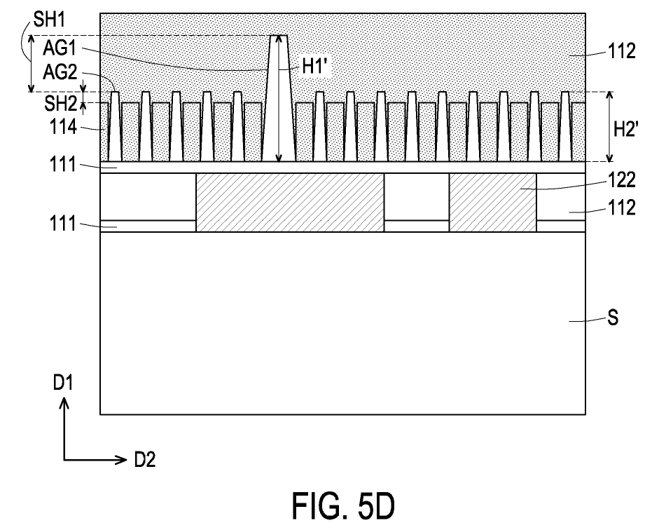

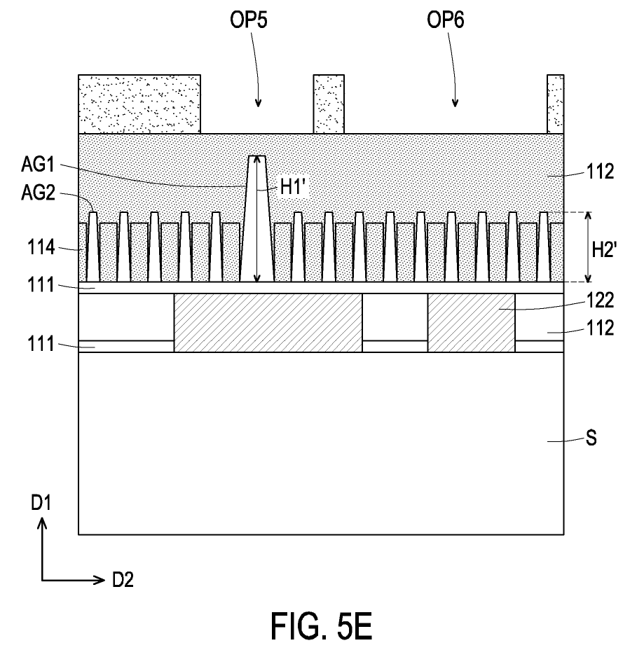

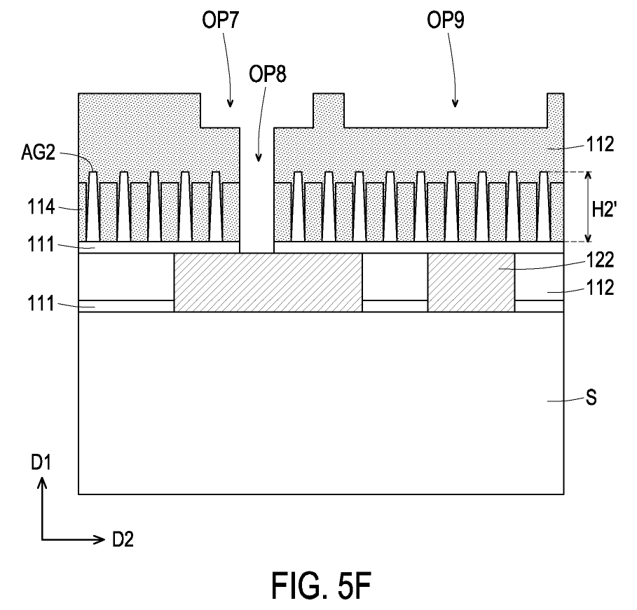

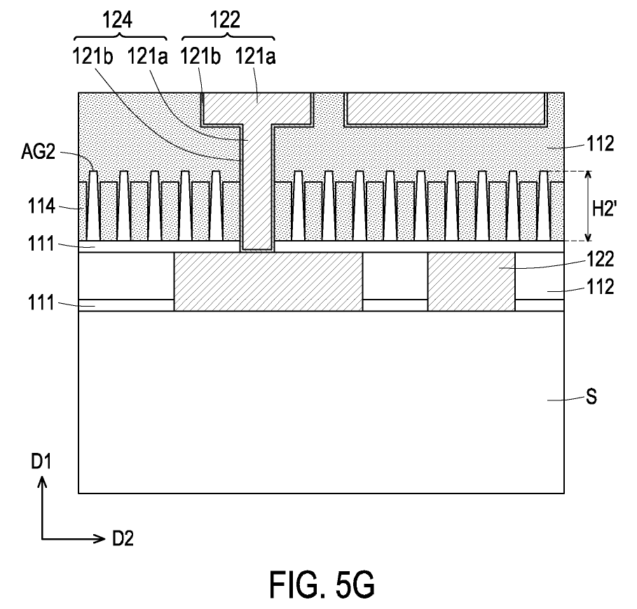

FIG. 4 is a schematic cross-sectional view of a semiconductor device according to some embodiments. The semiconductor device of FIG. 2 is similar to the semiconductor device of FIG. 1G, and the difference lies in the formation of the interconnect structure 110 of the interposer 100. In some embodiments, at least one dielectric layer 114 (e.g., 114-1…114-(n+1)) and the overlying dielectric layer 112 (e.g., 112-2…112-(n+2)) and the respective conductive features 124, 122 therein may be formed by a method illustrated in FIG. 5A to FIG. 5G.

Referring to FIG. 5A, a dielectric layer 112 is provided over a structure S, and a plurality of conductive features 122 are formed in the dielectric layer 112. The structure S may be the substrate 102 or any dielectric layer 114 of FIG. 4. In other words, the dielectric layer 112 may be any one of dielectric layers 112 of FIG. 4. Then, a dielectric layer 114 is formed on the dielectric layer 112 along a direction D1 (e.g., z direction). The dielectric layer 114 may have a thickness T1 in a range of 1 μm to 2 μm, for example. In some embodiments, a material of the dielectric layers 112, 114 includes undoped silicate glass (USG) or doped silicate glass such as fluorinated silicate glass (FSG), phospho-silicate glass (PSG), boro-silicate glass (BSG), boron-doped phospho-silicate glass (BPSG), silicon oxide, the like, or a combination thereof. The dielectric layers 112, 114 may be deposited by chemical vapor deposition (CVD), physical vapor deposition (PVD), atomic layer deposition (ALD), a spin-on-dielectric (SOD) process, the like, or a combination thereof. In some embodiments, an etch stop layer 111 is respectively formed directly below the dielectric layers 112, 114. The materials and forming methods of the etch stop layer 111 are similar to those described with reference to FIG. 1A, so the detailed descriptions thereof are omitted herein.

Referring to FIG. 5B, a patterned photoresist PR1 is formed on the dielectric layer 114. First, a photoresist (not shown) may be formed on the dielectric layer 114 by spin coating or the like. The photoresist may be a photosensitive material, which includes organic materials, and may be a positive photosensitive material or a negative photosensitive material. Then, the photoresist may be exposed to light for patterning, to form the patterned photoresist PR1. In some embodiments, the patterned photoresist PR1 includes at least one opening OP1 and a plurality of openings OP2 laterally surrounding the opening OP1. In some embodiments, the opening OP1 has a size (e.g., width and/or length) larger than a width of each of the openings OP2.

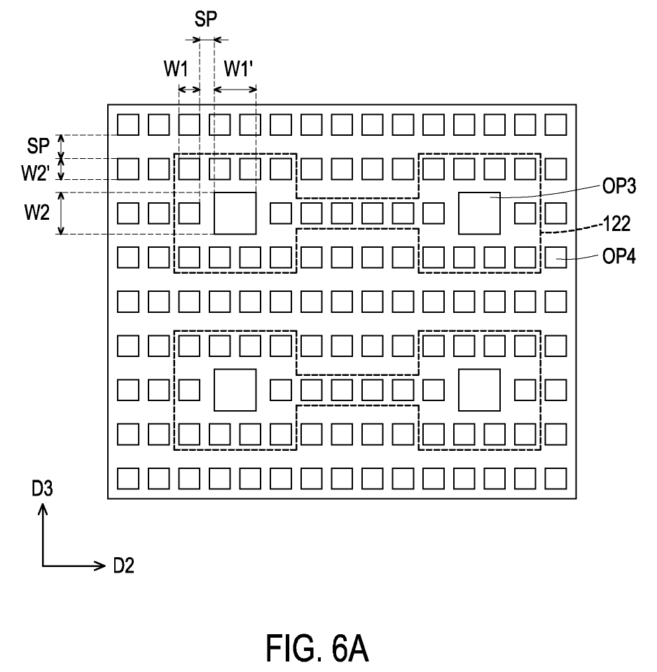

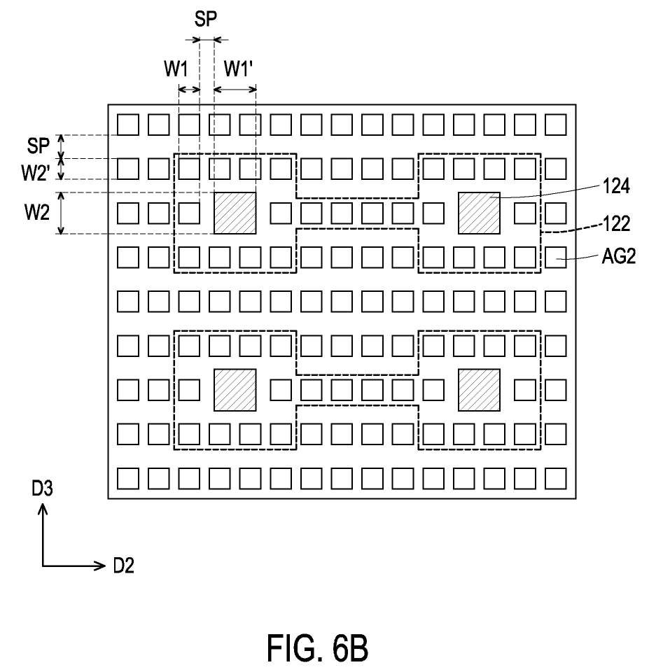

Referring to FIG. 5C, the dielectric layer 114 is patterned by using the patterned photoresist PR1 as a mask, to form a plurality of openings OP3, OP4 in the dielectric layer 114. The openings OP3, OP4 may be formed by removing portions of the dielectric layer 114. The removal method may include an etch process such as a dry etch process or a wet etch process. The openings OP3 is, for example, directly formed on the conductive feature 122 in the underlying dielectric layer 112. In some embodiments, as shown in FIG. 5C and FIG. 6A, the openings OP3 are laterally surrounded by the openings OP4. The openings OP3, OP4 may be substantially arranged in an array. The opening OP3 has a size larger than the opening OP4. For example, the opening OP3 has a width W1 along a direction D2 (e.g., x direction) and a width W2 along a direction D3 (e.g., y direction), and the opening OP4 has a width W1’ smaller than the width W1 along the direction D2 and a width W2’ smaller than the width W2 along the direction D3. The directions D1, D2 and D3 are substantially perpendicular to one another, for example. In some embodiments, the width W1, W2 is in a range of 0.7 μm to 1 μm, and the width W1’, W2’ is smaller than 0.5 μm and may be in a range of 0.3 μm to 0.35 μm. A spacing SP between the openings OP3 and OP4 or the openings OP4 is in a range of 0.4 μm to 0.6 μm, for example. In some embodiments, the opening OP3 is also referred to as a functional via opening, and the opening OP4 is also referred to as a dummy via opening. After formation of the openings OP3, OP4 in the dielectric layer 114, the patterned photoresist PR1 may be removed by an acceptable ashing or stripping process, such as using an oxygen plasma or the like.

Referring to FIG. 5D, a dielectric layer 112 is formed over the dielectric layer 114 to seal the openings OP3, OP4, and a plurality of air gaps AG1, AG2 are formed between the dielectric layers 114, 112. For example, the dielectric layer 112 is in direct contact with and bonded the underlying dielectric layer 114. The dielectric layer 112 has a thickness T2 in a range of 0.8 μm to 2 μm, for example. In some embodiments, a material of the dielectric layer 112 is formed on the dielectric layer 112 by a deposition process such as CVD. The material of the dielectric layer 112 may be similar to or the same as the dielectric layer 112 described with respect to FIG. 5A and may be the same as or different from the dielectric layer 114. The deposited material of the dielectric layer 112 may be overhang at the top of the openings OP3, OP4, and thus the openings OP3, OP4 are sealed to form the air gaps AG1, AG2. The air gaps AG1, AG2 may be also referred to as gap (if air does not exist therein), slots, pores, the like or a combination thereof. The air gaps AG1, AG2 are partially disposed in the dielectric layer 114 and partially disposed in the overlying dielectric layer 112. That is, a lower portion of the air gap AG1, AG2 are disposed in (e.g., surrounded by) the dielectric layer 114 and an upper portion of the air gap AG1, AG2 are disposed in (e.g., surrounded by) the overlying dielectric layer 112. The air gap AG1, AG2 are exposed to and in direct contact with the etch stop layer 111, for example. As shown in FIG. 5D, since the dielectric layer 112 partially fills the openings OP3, OP4, a shape of the air gap AG1, AG2 may be trapezoid or trapezoid-like. In other words, the air gap AG1, AG2 may have a top width larger than a bottom width, and a width of the air gap AG1, AG2 may decrease as the air gap AG1, AG2 becomes closer to a surface (e.g., top surface) of the overlying dielectric layer 112. However, the disclosure is not limited thereto. The air gap AG1, AG2 may have any suitable shape. In some embodiments, a height H1’ of the air gap AG1 is larger than a height H1 of the opening OP3 (also the thickness of the dielectric layer 114), a height H2’ of the air gap AG2 is larger than a height H2 of the opening OP4, and the height H1’ of the air gap AG1 is larger than the height H2’ of the air gap AG2. For example, the air gap AG1 has the height H1’ larger than 2.5 μm, and the H2’ of the air gap AG2 is larger than 2 μm. In some embodiments, as shown in FIG. 5D, an interface IN may exist between the dielectric layer 114 and the overlying dielectric layer 112. The interface IN is illustrated as a straight line, however, the interface IN between the dielectric layer 114 and the overlying dielectric layer 112 may be curved or the like depending on the deposition of the material of the overlying dielectric layer 112. In alternative

embodiments in which the dielectric layer 114 and the overlying dielectric layer 112 are of the same material, an interface may not exist or not be observable between the dielectric layer 114 and the overlying dielectric layer 112. It is noted that the dielectric layer 114 and the overlying dielectric layer 112 are illustrated with dots to clearly show the air gaps therein and it is not used to intend the materials of the dielectric layer 114 and the dielectric layer 112 are the same or different.

In some embodiments, heights SH1, SH2 shown in FIG. 5D may be also referred to as seal heights. The height SH1 may be controlled by the width W1, W2 of the opening OP3 in the dielectric layer 114, and similarly, the height SH2 may be controlled by the width W1’, W2’ of the opening OP4 in the dielectric layer 114. For example, the heights SH1, SH2 are controlled such that the conductive feature 124 (e.g., functional via) (shown in FIG. 5G) to be formed has a height H11 larger than the height H2’ of the air gap AG2 (e.g., dummy via).

Referring to FIG. 5E, a patterned photoresist PR2 having openings OP5, OP6 is formed on the dielectric layer 114. The opening OP5 is formed directly over the air gap AG1, and the opening OP6 is formed aside the opening OP6 and directly over some of the air gaps AG2, for example. The openings OP5, OP6 have a width corresponding to conductive features 122 (as shown in FIG. 5G) such conductive lines to be formed. In some embodiments, the opening OP5 has a width larger than a width of the air gap AG1.

Referring to FIG. 5F, by using the photoresist PR2 as a mask, portions of the dielectric layers 114 and 112 are removed, to form openings OP7, OP8 and OP9 in the dielectric layer 112. The openings OP7, OP8 and OP9 may be formed by removing portions of the dielectric layers 114 and 112 and the etch stop layer 111 with an etch process such as a dry etch process or a wet etch process. In some embodiments, the opening OP7 exposes the air gap AG1, and thus an opening OP8 is formed from the air gap AG1 and is connected to the opening OP7. The opening OP7 may be formed in the dielectric layer 112, and the opening OP8 may be formed in both dielectric layers 112 and 114. The opening OP8 may expose the underlying conductive feature 122 in the underlying dielectric layer 112. In some embodiments, the opening OP9 corresponding to the opening OP6 is formed aside the opening OP7 in the dielectric layer 112, and the opening OP9 is formed over the air gaps AG2. A depth of the opening OP9 may be substantially the same as a depth of the opening OP7. In some embodiments, the openings OP7, OP9 are also referred to as trench openings, and the opening OP8 is also referred to as a via opening.

Referring to FIG. 5G, a conductive feature 124 is formed in the opening OP8, and a conductive feature 122 is formed in the opening OP7. In some embodiments, the conductive feature 122 and the underlying conductive feature 124 are formed by a same process such as a dual damascene process. For example, a barrier material is formed on sidewalls and bottom surfaces of the openings OP7, OP8 and a conductive material is then formed to fill up the openings OP7, OP8. After that, excess conductive material and barrier material outside the openings OP7, OP8 may be removed by a planarization process such as CMP, to form the conductive feature 124 in the opening OP8, and the conductive feature 122 in the opening OP7. The conductive feature 124 (e.g., conductive via) is in direct contact with the overlying conductive feature 122 (e.g., conductive line) and the underlying conductive feature 122 (e.g., conductive line), for example. In some embodiments, the conductive feature 124 and the conductive feature 122 respectively include a conductive layer 121a and a barrier layer 121b surrounding the conductive layer 121a. A surface (e.g., top surface) of the overlying conductive feature 122 is substantially coplanar with a surface (e.g., top surface) of the overlying dielectric layer 112. For example, surfaces (e.g., top surfaces) of the conductive layer 121a and the barrier layer 121b are substantially coplanar with a surface (e.g., top surface) of the dielectric layer 112. A height H1 of the conductive feature 124 is larger than the thickness T1 of the dielectric layer 114, in other words, the conductive feature 124 is partially disposed in the dielectric layer 114 and partially in the overlying dielectric layer 112, for example. The height H1 of the conductive feature 124 is also larger than the height H2’ of the air gap AG2, for example. That is, a surface (e.g., top surface) of the conductive feature 124 is higher than a surface (e.g., top surface) of the air gap AG2. A width of the air gap AG1 may decrease as the air gap AG2 becomes closer to the overlying conductive feature 122. A height H2 of the overlying conductive feature 122 is smaller than the thickness T2 of the overlying dielectric layer 112, for example.

As shown in FIG. 6B, from a top view, the air gaps AG2 may be arranged to laterally surround the conductive feature 124 (e.g., conductive via). The air gaps AG2 may be also arranged to laterally surround the conductive feature 122 (e.g., conductive line) in the underlying dielectric layer 112. The air gaps AG2 are substantially arranged in an array, for example. In some embodiments, the conductive feature 124 may be also referred to as functional feature (e.g., functional via), and the air gap AG2 may be also referred to as dummy feature (e.g., dummy via). In some embodiments, the dielectric layer 114 has a plurality of air gaps AG2 therein, and thus the dielectric layer 114 may be also referred to as a porous structure. In some embodiments, the dielectric layer 114 and the overlying dielectric layer 112 may be also collectively referred to as a composite dielectric layer, and the composite dielectric layer has a large total thickness. In some embodiments, it is noted that there is no etch stop layer between the dielectric layer 114 and the overlying dielectric layer 112.

In some embodiments, the dielectric layer 114 has a plurality of air gaps AG2 therein, and thus the effective dielectric constant may be lowered. For example, the dielectric constant of the dielectric layer 114 (e.g., USG) without the air gaps AG2 is about 4.3, and the dielectric constant of the dielectric layer 114 (e.g., USG) with the air gaps AG2 is in a range of 2.1 to 4.2. Thus, the parasitic capacitance (e.g., intra-layer parasitic capacitance) formed between the conductive features (e.g., conductive feature 122-1 and conductive feature 122-2) may be also reduced. Accordingly, the interposer 100 may provide low insertion loss and improved signal integrity and/or electrical performance for the integrated circuits 130a, 130b such as HBM (high bandwidth memory) and SoC (system on integrated circuit). Accordingly, the interposer is suitable for the semiconductor device such as HPC (high performance computing) device which requires high speed and/or frequency electrical performance application in 3DIC. Furthermore, the warpage caused by the interposer may be also prevented, and thus a reliable semiconductor device such as package structure may be obtained.

In above embodiments, the dielectric layer 114 and the overlying dielectric layer 112 is formed by using one of the methods depicted in FIG. 1A to FIG. 1C, FIG. 3A to FIG. 3J and FIG. 5A to FIG. 5G. However, the disclosure is not limited thereto. The dielectric layer 114 and the overlying dielectric layer 112 and the conductive features 122, 124 therein may be formed by a combination of the method depicted in FIG. 1A to FIG. 1C, FIG. 3A to FIG. 3J and FIG. 5A to FIG. 5G. In other words, the interconnect structure 110 of the interposer 100 may be formed by using different methods as depicted in FIG. 1A to FIG. 1C, FIG. 3A to FIG. 3J and FIG. 5A to FIG. 5G. Furthermore, although the methods as depicted in FIG. 1A to FIG. 1C, FIG. 3A to FIG. 3J and FIG. 5A to FIG. 5G are illustrated for forming the interconnect structure of the interposer, the disclosure is not limited thereto. In other words, the methods as depicted in FIG. 1A to FIG. 1C, FIG. 3A to FIG. 3J and FIG. 5A to FIG. 5G may be used for forming interconnect structure in the die, the redistribution layer structure in the semiconductor package or any other interconnect structure.

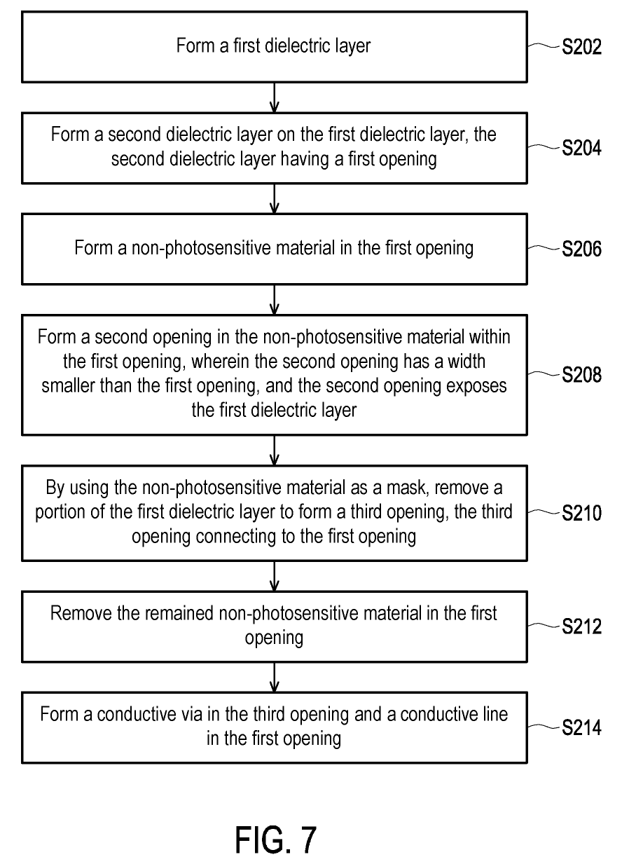

FIG. 7 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S202, a first dielectric layer is formed. FIG. 3A illustrates a view corresponding to some embodiments of act S202.

At act S204, a second dielectric layer is formed on the first dielectric layer, and the second dielectric layer has a first opening. FIG. 3B and FIG. 3C illustrate views corresponding to some embodiments of act S204.

At act S206, a non-photosensitive material is formed in the first opening. FIG. 3D illustrates a view corresponding to some embodiments of act S206.

At act S208, a second opening is formed in the non-photosensitive material within the first opening, wherein the second opening has a width smaller than the first opening, and the second opening exposes the first dielectric layer. FIG. 3E to FIG. 3G illustrate views corresponding to some embodiments of act S206.

At act S210, by using the non-photosensitive material as a mask, a portion of the first dielectric layer is removed to form a third opening, the third opening connecting to the first opening. FIG. 3H illustrates a view corresponding to some embodiments of act S210.

At act S212, the remained non-photosensitive material in the first opening is removed. FIG. 3I illustrates a view corresponding to some embodiments of act S212.

At act S214, a conductive via is formed in the third opening and a conductive line is formed in the first opening. FIG. 2 and FIG. 3J illustrate views corresponding to some embodiments of act 214.

According to some embodiments, a semiconductor device includes an interconnect structure. The interconnect structure includes a first conductive line in a first dielectric layer, a conductive via in a second dielectric layer and a second conductive line in a third dielectric layer. The second dielectric layer is disposed between the first and third dielectric layers, and a dielectric constant of the second dielectric layer is smaller than a dielectric constant of the first dielectric layer and a dielectric constant of the third dielectric layer.

According to some embodiments, a semiconductor device includes an interconnect structure. The interconnect structure includes a conductive feature in a first dielectric layer and a conductive via in a second dielectric layer over the first dielectric layer and electrically connected to the conductive feature. The second dielectric layer includes a plurality of air gaps, and the air gaps laterally surround the conductive via.

According to some embodiments, a method of forming a semiconductor device includes following steps. A first dielectric layer is formed. A second dielectric layer is formed on the first dielectric layer, and the second dielectric layer has a first opening. A non-photosensitive material is formed in the first opening. A second opening is formed in the non-photosensitive material within the first opening, wherein the second opening has a width smaller than the first opening, and the second opening exposes the first dielectric layer. By using the non-photosensitive material as a mask, a portion of the first dielectric layer is removed to form a third opening, the third opening connecting to the first opening. The remained non-photosensitive material in the first opening is removed. A conductive via is formed in the third opening and a conductive line is formed in the first opening.

According to some embodiments, a semiconductor device includes an interconnect structure. The interconnect structure includes a first conductive line in a first dielectric layer, a conductive via in a second dielectric layer, a second conductive line in a third dielectric layer and an etch stop layer. The second dielectric layer is disposed between the first and third dielectric layers, and a dielectric constant of the second dielectric layer is smaller than a dielectric constant of the first dielectric layer and a dielectric constant of the third dielectric layer. The etch stop layer is disposed directly below at least one of the first to third dielectric layers.

According to some embodiments, a semiconductor device includes a conductive via in a first dielectric layer, a second dielectric layer and at least one air gap. The at least one air gap is disposed between the first dielectric layer and the second dielectric layer.

According to some embodiments, a method of forming a semiconductor device includes following steps. A first dielectric layer having a plurality of openings is formed. A second dielectric layer is formed on the first dielectric layer, to form a plurality of air gaps between the first dielectric layer and the second dielectric layer. A conductive pattern is formed in the first dielectric layer and the second dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an interconnect structure, comprising:
a first conductive line in a first dielectric layer, a conductive via in a second dielectric layer and a second conductive line in a third dielectric layer, wherein the second dielectric layer is disposed between the first and third dielectric layers, and a dielectric constant of the second dielectric layer is smaller than a dielectric constant of the first dielectric layer and a dielectric constant of the third dielectric layer; and
an etch stop layer directly below at least one of the first to third dielectric layers.

2. The semiconductor device of claim 1, wherein a difference between the dielectric constant of the first dielectric layer and the second dielectric layer is not smaller than 0.5, and a difference between the dielectric constant of the third dielectric layer and the second dielectric layer is not smaller than 0.5.

3. The semiconductor device of claim 1, wherein the dielectric constant of the second dielectric layer is in a range of 2.5 to 3.5, the dielectric constant of the first dielectric layer is in a range of 3.5 to 4.5, and dielectric constant of the third dielectric layer is in a range of 3.5 to 4.5.

4. The semiconductor device of claim 1, wherein a thickness of the second dielectric layer is respectively smaller than a thickness of the first dielectric layer and a thickness of the third dielectric layer.

5. The semiconductor device of claim 1, wherein the etch stop layer is directly below the first to third dielectric layers respectively.

6. A semiconductor device, comprising:
a conductive via in a first dielectric layer and a second dielectric layer; and
at least one air gap, wherein the at least one air gap is disposed between the first dielectric layer and the second dielectric layer.

7. The semiconductor device of claim 6, wherein the at least one air gap comprises a plurality of air gaps substantially arranged in an array.

8. The semiconductor device of claim 6, wherein a height of the conductive via is larger than a height of the at least one air gap.

9. The semiconductor device of claim 6, further comprising a conductive line disposed in the second dielectric layer and physically connected to the conductive via.

10. The semiconductor device of claim 6, wherein the first dielectric layer interfaces with the second dielectric layer.

11. The semiconductor device of claim 6, wherein the second dielectric layer is disposed on the first dielectric layer along a first direction, and a width of the at least one air gap along a second direction substantially perpendicular to the first direction decreases as the at least one air gap becomes closer to the second dielectric layer.

12. The semiconductor device of claim 6, further comprising a conductive line disposed in the second dielectric layer and physically connected to the conductive via, wherein a width of the at least one air gap decreases as the at least one air gap becomes closer to the conductive line.

13. The semiconductor device of claim 6, further comprising an etch stop layer directly below the first dielectric layer, wherein the at least one air gap is exposed to the etch stop layer.

14. The semiconductor device of claim 6, wherein the second dielectric layer is inserted into the first dielectric layer.

15. The semiconductor device of claim 6, wherein the at least one air gap comprises a plurality of air gaps, and the second dielectric layer is further disposed between the air gaps.

16. A method of forming a semiconductor device, comprising:
forming a first dielectric layer having a plurality of openings;
forming a second dielectric layer on the first dielectric layer, to form a plurality of air gaps between the first dielectric layer and the second dielectric layer; and
forming a conductive pattern in the first dielectric layer and the second dielectric layer.

17. The method of claim 16, wherein the air gaps are partially disposed in the first dielectric layer and partially disposed in the second dielectric layer.

18. The method of claim 16, wherein the plurality of openings comprise a first opening and a second opening having a width larger than the first opening.

19. The method of claim 18, wherein the plurality of air gaps comprise a first air gap corresponding to the first opening and a second air gap corresponding to the second opening and having a width larger than the first air gap.

20. The method of claim 19, wherein forming the conductive pattern comprises:
removing a portion of the second dielectric layer to expose the second air gap while the first air gap is covered by the second dielectric layer.
